(19) United States
(12) Patent Application Publication
(10) Pub. No.: US 2021/0312329 A1
(43) Pub. Date: Oct. 7, 2021

(54) REINFORCEMENT LEARNING FOR WEBSITE ERGONOMICS

(71) Applicant: Amadeus S.A.S., Biot (FR)

(72) Inventors: Thierry Delahaye, Bangkok (TH); David Renaudie, Valbonne (FR)

(21) Appl. No.: 17/204,469

(22) Filed: Mar. 17, 2021

(30) Foreign Application Priority Data
Apr. 2, 2020 (FR) 2003313

(51) Int. Cl. G06N 20/00; G06N 5/04; G06F 16/953; G06F 30/27; G06Q 50/30

(52) U.S. Cl. CPC G06N 20/00; G06N 5/04; G06Q 50/30; G06F 30/27; G06F 16/953

(57) ABSTRACT

Computer-implemented systems and methods for dynamically building and adapting a search website hosted by a webserver. A learning module is coupled to the webserver and employs a reinforcement learning model for controlling appearance and/or functionality of the search website by generating actions to be output to the webserver. The actions relate to controlling an order of elements in an ordered list of travel recommendations obtained as a result from a search request to be displayed by the search website and/or arranging web-site controls on the search website. The reinforcement learning module receives rewards that are generated by the search website based on user input on the search website or by a website user simulator in response to one or more of the actions generated by the learning module based on state information provided by the user simulator. The rewards make the learning module to adapt the learning model.

### TECHNICAL FIELD

The disclosure of the present invention generally relates to computers and computer software, and in particular to methods, systems, and computer program product that handle search queries in a database system and perform cache update adaptation.

### BACKGROUND

Recommendation for certain products, certain information etc. is crucial in both academia and industry, and various techniques are proposed such as content-based collaborative filtering, matrix factorization, logistic regression, factorization machines, neural networks and multi-armed bandits. Common problems with these approaches are that (i) the recommendation is considered as a static procedure and the dynamic interactive nature between users and the recommender systems is ignored; (ii) focus is put on the immediate feedback of recommended items and the long-term rewards are neglected. One general approach to shorten response times to queries is to pre-compute or pre-collect results to search queries and maintain them in a cache. Search queries are then actually not processed on the large volumes of original data stored in data bases, but on the results as maintained in the cache.

Recommender systems with user interaction are described, for example, in Deep Reinforcement Learning based Recommendation with Explicit User-Item Interactions Modeling by Feng Liu et al., Deep Neural Networks for Choice Analysis: A Statistical Learning Theory Perspective by Shenhao Wang et al., Deep Choice Model Using Pointer Networks for Airline Itinerary Prediction by Alejandro Mottini and Rodrigo Acuna-Agost, and DRN: A Deep Reinforcement Learning Framework for News Recommendation by Guanjie Zheng et al.

What is needed, however, is a Reinforcement Learning (RL) algorithm for increasing the number of completed transactions via a website of an online travel agency (OTA), i.e., increase the rate of conversions of users just browsing through the website to actual customers.

### SUMMARY

In an embodiment, a computer-implemented system for dynamically building and adapting a search website hosted by a webserver is provided. The system includes a Reinforcement Learning module coupled to the webserver and employing a Reinforcement Learning model for controlling appearance and/or functionality of the search website by generating actions to be output to the webserver. The actions relate to controlling an order and/or rank of elements in an ordered list of travel recommendations obtained as a result from a search request to be displayed by the search website and/or arranging website controls on the search website. The Reinforcement Learning module is adapted to receive Reinforcement Learning rewards. The Reinforcement Learning rewards are generated by the search website based on user input on the search website or by a website user simulator in response to one or more of the actions generated by the Reinforcement Learning module based on state information provided by the user simulator. The rewards make the Reinforcement Learning module to adapt the Reinforcement Learning model. The website user simulator is configured to simulate an input behavior of users of the search website and feed the Reinforcement Learning module to train the Reinforcement Learning module.

In some embodiments, the search website may be a travel website for booking travel products and the actions may comprise sorting travel products to be displayed on the travel website in response to a user search request according to one or more characteristics of the travel products and/or controlling an appearance of the website controls to be shown on the travel website.

In some embodiments, the one or more characteristics of the travel product include a price, a duration of the travel product, a number of stops, a departure time, an arrival time, a type of travel provider, or a combination thereof.

In some embodiments, the website user simulator comprises a simulation model with at least one of the following parameters describing the user input behavior: a passenger segment, search behavior according to a passenger type, intention to book at a later point of time after a current search, intention to conduct another search after the current search.

In some embodiments, the passenger segment includes one or more of: business passenger, leisure passenger, senior passenger, passenger visiting friend and relatives.

However, although the segment of the user influences the search that will be done on the website or the searches simulated by the user simulator and the user behavior (booking/other search/leaving) and the user will be given a certain order or rank of elements in an ordered list of travel recommendations and/or website controls provided by the Reinforcement Learning algorithm, the segment is not directly observed by the Reinforcement Learning module to provide a realistic approach.

In some embodiments, the passenger type is specified by one or more of: day of the week for searching, time of the day for searching, number of seats, number of days until departure, Saturday night stay, importance of travel product characteristics.

In some embodiments, the rewards relate to the user booking one of the travel products displayed on the travel website.

A system according to any of the above-mentioned embodiments is also provided, and further includes the webserver hosting the search website.

The above summary may present a simplified overview of some embodiments of the invention in order to provide a basic understanding of certain aspects the invention discussed herein. The summary is not intended to provide an extensive overview of the invention, nor is it intended to identify any key or critical elements, or delineate the scope of the invention. The sole purpose of the summary is merely to present some concepts in a simplified form as an introduction to the detailed description presented below.

### BRIEF DESCRIPTION OF THE DRAWINGS

The accompanying drawings, that are incorporated in and constitute a part of this specification, illustrate various embodiments of the invention and, together with the general description of the invention given above, and the detailed description of the embodiments given below, serve to explain the embodiments of the invention.

FIG. 1 schematically depicts the computer-implemented system connected to a webserver hosting a search website.

FIG. 2 visualizes the information presented on a search website.

FIG. 3 visualizes the input parameters affecting a simulation model of a website user simulator.

FIG. 4 visualizes an interaction between a website user simulator and a Reinforcement Learning algorithm.

FIG. 5 depicts an interrelation between environmental parameters and a Reinforcement Learning model.

FIG. 6 visualizes a flight search environment in conjunction with a Reinforcement Learning model.

FIG. 7 depicts an example of a search tree considering whether or not there are found results and whether or not there is an intent to book.

FIG. 8 depicts another example of a search tree similar to the search tree of FIG. 7, but also considering an intent to leave.

FIG. 9 visualizes the relation between the amount of days before departure of a travel product and the number of requests for such a travel product.

FIG. 10 depicts a learning curve of a Reinforcement Learning model.

FIG. 11 depicts a computer system on which the method described can be implemented.

### DETAILED DESCRIPTION

A website user simulator simulates an interaction of the website, which displays search results e.g., for a particular travel itinerary requested by a simulated user. Based on the simulated, i.e., expected, reaction of the user to the displayed search results, more precisely to the way the search results are displayed to him/her, as well as the graphic interfaces and usage of functionalities on the website, a Reinforcement Learning model is adjusted to ergonomically enhance the user experience, by displaying the search results and graphical interfaces according to the user's preferences.

In order to be able to adapt and change the display and representation of requested search results on a search website e.g., of an online travel agency (OTA) with regard to the likes and dislikes of the user who requested the search results, the Reinforcement Learning model is used as a recommender system, meaning the best suited results of the particular user are recommended to him/her. In order to learn the best-suited result and/or website functionalities website controls for a particular user, the website user simulator is used to train the Reinforcement Learning model. The specification sets forth the general principles of the website presentation improvement by way of example using the travel sector, i.e., a user searching and/or booking travel products via the OTA website. However, the general principles are applicable to any search website which displays search results in response to search requests.

In order to address the above-mentioned difficulties, it is therefore generally proposed herein to utilize a Reinforcement Learning algorithm which dynamically optimizes the decision of the number of travel recommendations presented as search results and the order or rank of elements in an ordered list of travel recommendations as search result to be displayed to the user.

Employing a standard supervised learning algorithm, where the algorithm learns using labels on past data poses difficulties since there is no knowledge of which display scheme is optimal for a given share of query results for a particular user. The required expert knowledge is generally not available since the data set from which the expert obtained his/her knowledge is usually too small for a reliable recommendation to be presented for a vast majority of users with varying preferences.

Another way to build this database would be to use a brute force approach to permute all possible orders or ranks of elements in an ordered list of travel recommendations to be displayed by the search website and/or to arrangements of website controls on the search website and compare the arrangements with a number of booked travel products for every arrangement. This could yield a determination which rank and/or order of elements in an ordered list of travel recommendations/website control arrangement is the most appropriate to maximize the number of booked travel products. However, this approach has technical drawbacks, for example, it would take a lot of computation time and hardware resources to gather all these statistics, so that such an approach seems to be nearly technically infeasible in practice.

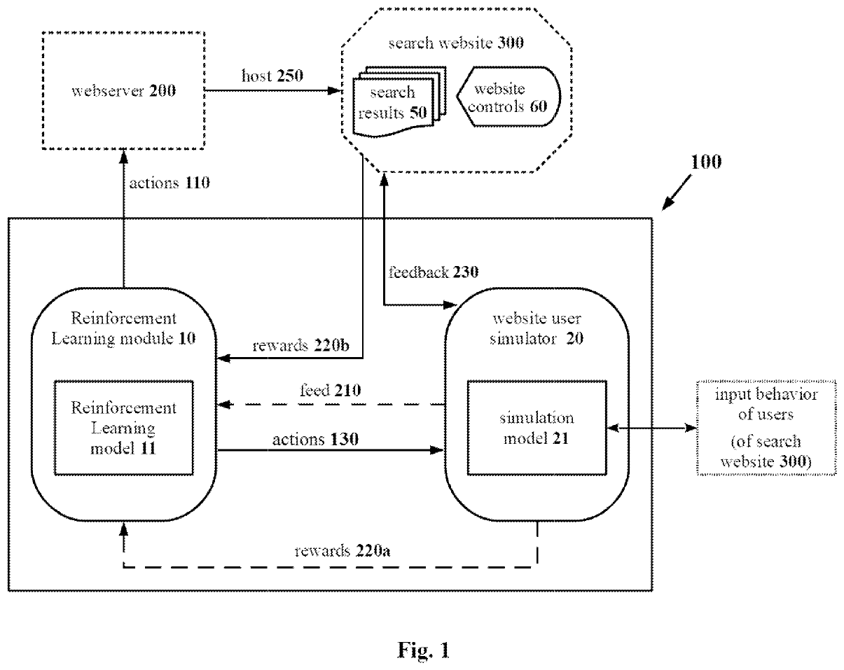

An example of a computer-implemented system to overcome these drawbacks is shown in FIG. 1. The system is connected to a webserver hosting a search website and employs a user simulator and a Reinforcement Learning module to achieve an ergonomically improved website design and functionality.

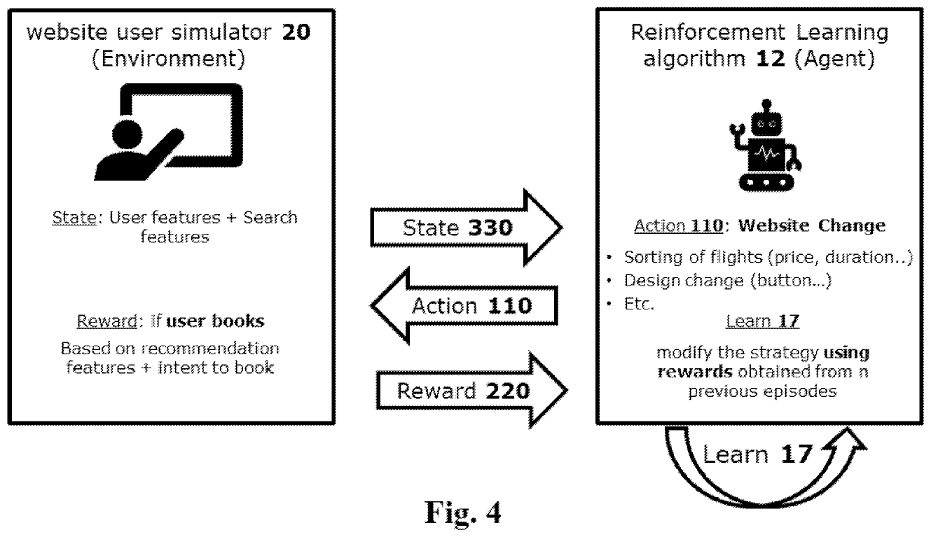

It is proposed herein to train a Reinforcement Learning algorithm 12 (see FIG. 4) adapting the order and/or rank of elements in an ordered list of travel recommendations to be displayed by the search website 300 and/or arrangements of website controls 60 on the search website continuously in the course of processing simulated user inputs. The simulated user inputs are, for example, a simulated behavior of a user navigating through a travel product search website. These simulated user inputs might reflect the differences between certain segments of users, for example, users performing a business-related or a leisure-related query. The simulated user actions are provided to the Reinforcement Learning module 10 via a feed 210.

Positive/negative booking results for travel products achieved using a certain order and/or rank of elements in an ordered list of travel recommendations and/or website controls arrangement on the search website are, for example, fed to the learning algorithm as a positive/negative reward 220. In the learning phase of the system, the Reinforcement Learning module 10 may report actions 130, such as a change in the order and/or rank of elements in an ordered list of travel recommendations and/or a change of website control arrangements, which were performed by the Reinforcement Learning module 10 to the website user simulator 20. In the actual production phase, with real users and searchers on the search website 300, the webserver 200 hosting the search website 300 will send feedback via its website engine to help the website user simulator 20 to reproduce some user browsing actions.

In general, the system 100 is enhanced with a Reinforcement Learning module 10 employing a Reinforcement Learning model 11 to determine an optimal order and/or rank of elements in an ordered list of travel recommendations and/or website controls arrangement on the search website 300, which is hosted 250 on a webserver 200.

More specifically, the Reinforcement Learning module 10 receives the feed 210 from a website user simulator 20. The feed 210 is a set of inputs simulated by the website user simulator, for example, a simulated query for a certain leisure-related/business-related travel product on a simulated day of week/time of day and/or a simulated timespan before departure. The website user simulator 20 might present actions that stem from a simulation model 21, programmed to simulate a behavior of a particular type of user. The simulation model 21 might be developed based on input behavior of the search website 300 of e.g., millions of different users with a certain quality (age, purpose of trip) in common. The simulation model 21 may be a model based on a multilayer neural network or deep neural network.

The Reinforcement Learning module 10 forwards the simulated query to the search website 300 having certain website controls 60. The search website 300 yields a search result, comprised of an ordered list of travel recommendations. The user simulator 20 now simulates the navigation behavior of a user. The simulated user as well as a real user may perform several successive search requests on the website, and will typically change some search parameters, such as origin and destination, the outbound and inbound dates or other options. After each search request issued by the user, the Reinforcement Learning module may change the order and/or rank of elements in an ordered list of travel recommendations. The simulated user behavior results in a book or not book decision—which is fed forward as a respective positive/negative decision to the Reinforcement Learning module 10. The simulated user, as well as real user may belong to a certain segment (e.g., businessman traveler, holiday traveler etc.) and might be simulated to behave as such.

Key performance indicators (KPIs) may be used to rate a certain order of elements in the ordered list of travel recommendations yielded as a search result and a certain arrangement of the website controls on the search website. For example, a KPI may refer to a booking percentage. The more travel products are actually booked with a rated configuration in a certain time, the higher this KPI may be.

Expert knowledge may be used to determine e.g., which options of arranging the website controls and/or the order or rank of elements in the ordered list of travel recommendations will most probably not have an influence on the KPIs—this can be used to reduce the dimensionality of the learning space.

The values of the individual KPIs may be aggregated to an aggregated value of KPIs as explained in more detail below. The KPIs may be hierarchically defined, with more general KPIs being composed of a number of more specific KPIs. KPI aggregation is then done at each hierarchy level, wherein more specific KPIs are aggregated to form the more general KPI and the more general KPIs are aggregated to establish a common reward value for a certain action.

Before discussing the present Reinforcement Learning (RL) system in more detail, we first give an overview of some general underlying concepts of Reinforcement Learning. Reinforcement Learning mechanisms are also described, for example, by the textbook “Reinforcement Learning” by Richard S. Sutton and Andrew G. Barto, published by the MIT Press in 1998. RL mechanisms utilize state-of-the-art terms having an established meaning and are used herein in this established meaning to describe the algorithm for determining an optimal order and/or rank of elements in an ordered list of travel recommendations and/or website controls arrangement, including:
agent: the module that learns and makes decisions (here: the Reinforcement Learning module 10),
environment: all facts outside the agent with which the agent interacts at each of a sequence of discrete points in time. The environment influences decisions by the agent and is influenced by the agent's decisions (here: the simulated user behavior created by website user simulator 20).
task: a complete specification of an environment, one instance of the reinforcement learning problem (here: e.g., a simulation of a certain segment of users (e.g., business travelers for a certain amount of time)).
observation: determination of a state of the environment at a discrete point in time (here: e.g., the evaluation of booking success for some different sortings of search results and arrangements of website controls on the website).
state: a combination of all features describing the current situation of the agent and/or the environment.
action: decision taken by the agent from a set of actions available in the current state of the environment (here: e.g., the action of sorting results by their departure date and not their price for business users).
policy: mapping from the states of the environment to probabilities of selecting each possible action (here: e.g., developing a rule that for a certain segment a certain arrangement of controls on the website might be advantageous).
reward function: function determining a reward to each action selected by the agent.
value function: a table that associates a set of actions (here: e.g., a set of sorting criteria applied to the search results) with their estimated reward.

The goal of the agent is to maximize the rewards not immediately, but in the long run. Hence, a long-term reward is estimated.

A general feature of Reinforcement Learning is the trade-off between exploration and exploitation:
In exploration mode, the agent tries out new kinds of actions to see how effective they are. The effectiveness of an action is immediately given by the reward returned to the agent in response to the selected action.
In exploitation mode, the agent makes use of actions that are known to yield a high reward using of the history of rewards derived from a value function. More specifically, during each exploitation phase, the arrangement of control buttons and/or the order and/or rank of elements in an ordered list of travel recommendations is determined that is currently known to yield the most rewards. The aim is to maximize the rewards on the long run (mathematically, this means that the sum of all rewards on an infinite lifespan is maximized). Generally spoken, in exploitation mode, the algorithm tries to make profit of what it has learned, whereas the exploration mode can be considered as an “investment” to look for other opportunities to further optimize the ergonomic characteristics of the search website's user interface (search result order, website functionalities, etc.).

The agent continuously learns in exploration and in exploitation mode from its environment—in the example of FIG. 1—from the simulated decisions made by the website user simulator 20. However, exploration and exploitation should be balanced.

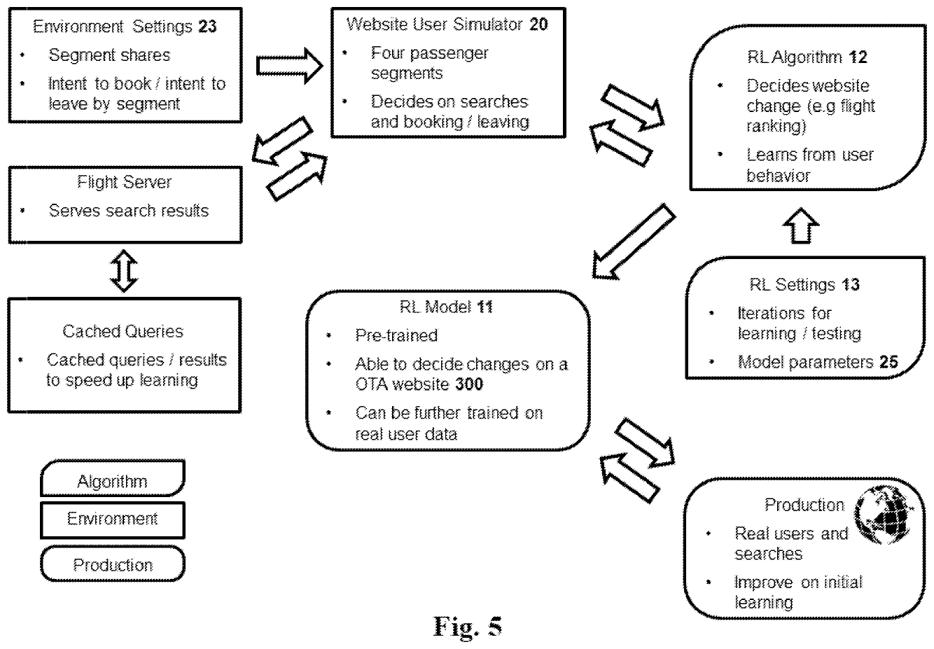

Further particularities of the Reinforcement Learning algorithm design to implement the Reinforcement Learning module 10 with the Reinforcement Learning model 11 are described next with reference to FIGS. 4 and 5. The website configuration determination algorithm may be composed of two main activities:
deciding on changes in the configuration of the website, such as website controls arrangement or as the order or rank of elements in an ordered list of travel recommendations, e.g., flight ranking. Here also the website's appearance can be changed, e.g., by changing the layout of the webpage (positions of respective elements top/bottom, left/right.), absence or presence of some banners, tuning the colors of some elements' text or background, etc. Furthermore, also the website's search results can be changed: by processing the results of a first, primary search results and choosing to filter out some of those results, putting in top position some others, or even requesting for more primary search results in the background.
learning from user behavior. The Reinforcement Learning algorithm is continuously learning from user behavior, including for fine-tuning purposes. In the Reinforcement Learning according to the current specification are two phases in Reinforcement Learning, namely a first phase, where the simulator is used for pre-training and then a second phase where real user traffic is used for learning. The agent, for example, executes an asynchronous process (FIG. 4: “Learn 17”) to collect history data from a statistics server, analyzes the data and fine-tunes the data basis for the appearance decisions of the website configuration. The history data may also be provided by a website user simulator 20, which constitutes the environment of the Reinforcement Learning Algorithm 12. Instead of using historic (real) user data, the RL algorithm 12 may operate on the basis of (simulated) user data provided by the website user simulator 20, which imitates the behavior of website users, in particular of people planning to purchase their next trip via the search website 300. When the Reinforcement Learning is performed using this user simulator, the Reinforcrment Learning algorithm 12 (agent) takes an action at each time step. As mentioned above, the action may be a change in the order or rank of elements in an ordered list of travel recommendations to be displayed as search results and/or a change in the website control arrangements.

More details of the RL mode determination are described next. As explained in the introduction of Reinforcement Learning above, a balanced tradeoff is sought between these two modes.

Two balancing methods may be applied during the learning phase, namely the Epsilon-Greedy strategy or the Softmax strategy. For example, the Epsilon-Greedy strategy may be used.

During a production phase (hence a phase with real (not simulated) users), either a full exploitation will be set or a small exploration with a low percentage (e.g., 5%) may be allowed.

Regarding the learning rates' development, a standard learning rate decay scheme may be used.

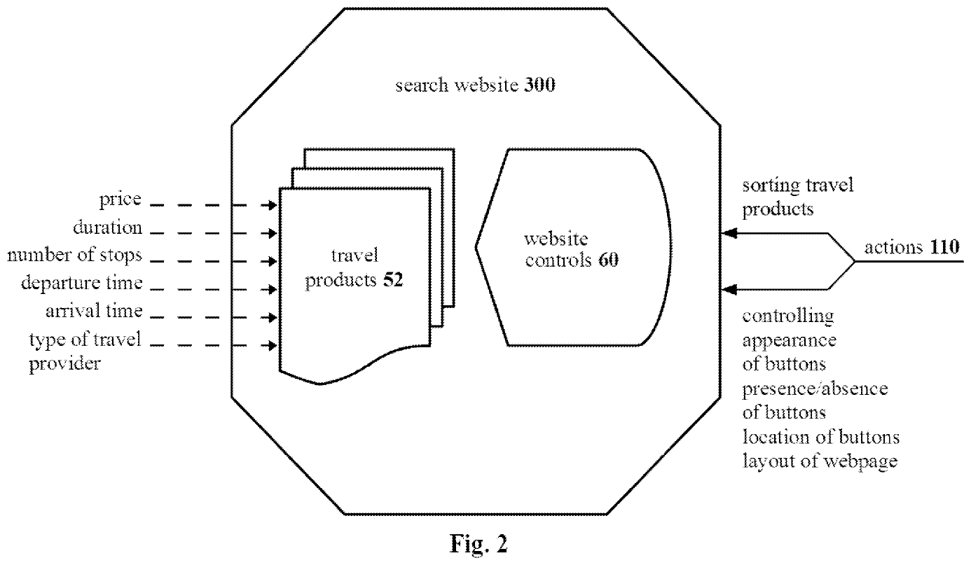

An exemplary visualization of information presented on a search website 300 is given by FIG. 2.

As mentioned above, in some examples, the search website is a travel website for booking travel products, and the actions comprise sorting travel products to be displayed on the travel website in response to a user search request according to one or more characteristics of the travel products and/or controlling an appearance of the website controls etc. to be shown on the travel website.

In some examples, the one or more characteristics of the travel product include a price, a duration of the travel product, a number of stops, a departure time, an arrival time, a type of travel provider, or a combination thereof.

Travel products 52, such as combined flights and hotel bookings, are displayed on the search website 300. The displayed travel products might comprise attributes such as a price, a duration, a number of stops, a departure time, an arrival time or a type of travel provider. The user is capable of selecting, rearranging, booking and so forth the travel products 52 via website controls 60. The Reinforcement Learning module 10 changes the appearance of the search website 300, in particular with respect to the rank and/or order of elements in the ordered list of travel recommendations displayed and the arrangement of the website controls 60. These changes are affected via actions 110 performed by the Reinforcement Learning module 10. As mentioned above and shown in FIG. 2, these actions 110 comprise the sorting of travel products and controlling the appearance of buttons, as well as decisions about the presence/absence of buttons, a location of buttons on the website, a layout of the webpage.

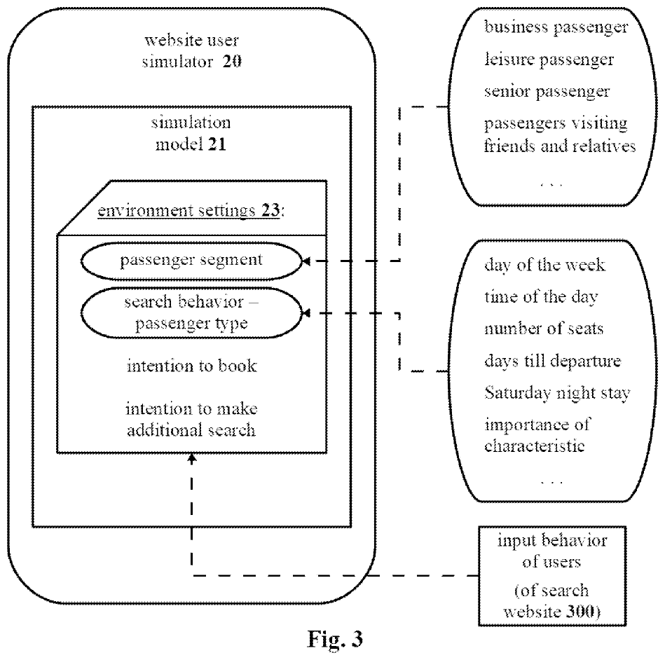

Examples of input parameters affecting a simulation model of a website user simulator are visualized by FIG. 3.

The website user simulator 20 comprises a simulation model 21. The simulation model 21 is a computational/mathematical model used to simulate the actions of particular users. The simulation model 21 is designed and continuously adapted based on input behavior of users, which make use of the search website 300 in order to book a particular travel product 52 (FIG. 2). The input behavior of real users may be continuously stored in a log file.

The simulation model 21 as well as the simulated actions output by the website user simulator 20 may reflect certain environment settings 23. These environment settings 23 comprise characteristics/preferences of the user such as a passenger segment, a search behavior/passenger type, an intention to book and an intention to make an additional search.

As such, in some examples, the website user simulator 20 comprises a simulation model 21 with at least one of the following parameters describing the user input behavior: a passenger segment, search behavior according to a passenger type, intention to book at a later point of time after a current search, intention to conduct another search after the current search.

In some examples, the passenger segment includes one or more of: business passenger, leisure passenger, senior passenger, passenger visiting friend and relatives.

These examples for passenger segments are now explained further: (i) business: a passenger who travels in the course of his or her business; (ii) leisure: a passenger who travels for vacation and wishes to book a hotel etc.; (iii) visiting friends and relatives: a passenger who travels to visit friends and relatives; (iv) senior: passengers users who have retired. Different segments may want to book different flights, such as the fastest flight, the cheapest flight, the most comfortable flight or a combination thereof.

An example for a search behavior/passenger type is the passenger type who just searches to receive information about existing flight connections and does not have a real intention to buy/book. Further examples for behavior/passenger type are (i) the day of the week a search for a travel takes place, (ii) the time of the day the search takes place, (iii) the number of seats that are intended (single booking, family booking), (iv) days till departure (some business passengers may tend to book closely before a planned stay some of them may however book half a year in advance, leisure passengers sometimes only book weeks in advance), (v) Saturday night stay, or (vi) an importance of characteristic (a user's priority of acquiring a travel product).

Search patterns may be estimated from past bookings received and/or stated preferences by a certain user segment. Those search patterns may not need to be fully accurate, but may be accurate enough to provide a basic pre-trained model.

An intention to book may indicate users who indeed intend to book a travel product 52 (see FIG. 2) on the search website 300 at question.

An intention to make an additional search and/or an intention to leave may indicate that the user uses the website 300 to search for a particular travel product, but will make a further search later after not booking the currently search product on the same website 300 or on a different website, for example, belonging to a different travel provider.

An example for an interaction between the website user simulator 20 and the Reinforcement Learning algorithm is visualized by FIG. 4.

The website user simulator 20, corresponding to the environment of the Reinforcement Learning module 10 (FIG. 1), simulates a user behavior on the search website. A current state 330 of the website user simulator 20 is defined by user features (e.g., details of the user model used for simulating passengers of a certain segment) and search features (weekend trip, long-time holiday or the like). The current state 330 of the website user simulator is forwarded to the Reinforcement Learning algorithm 12, corresponding to the agent of the Reinforcement Learning module 10 (FIG. 1).

The Reinforcement Learning algorithm 12 continuously performs actions 110 resulting in a change of the website 300 (FIG. 1). These website changing actions 110 comprise, for example, (i) sorting flights according to their price, their duration, number of stops, etc. (ii) a functionality change, such as changing the arrangement of buttons to click for a website user, and so forth. These actions 110 influence the website user simulator 20, since the simulated website user is confronted with a website 300 (FIG. 1) that has changed.

The website user simulator returns a reward 220 to the Reinforcement Learning algorithm 12, e.g., if the simulated user books a travel product 52 (FIG. 2).

Hence, in some examples, the rewards relate to whether or not the user books one of the travel products displayed on the travel website.

The reward 220 may be based on recommendation features. The recommendation features are travel recommendation features and relate to the features of a travel product. If a booking decision is positive, a reward will be sent to the Reinforcement Learning algorithm 12. There is a 1:1 mapping between a positive booking decision and the reward.

Based on the reward 220 received, the Reinforcement Learning algorithm 12 performs a learning activity 17, which may lead to a modified website changing strategy using the rewards obtained (or the change in rewards obtained) as a result of previous website changing actions 110 and user input on the website.

For example, the website user simulator 20 yields actions on the website that can be categorized to be the behavior of leisure segment users. The interactions of the simulated user with the website (but not the segment the user belongs to) might be forwarded to the Reinforcement Learning algorithm 12. The action “sort by price” might be performed on the search website 300 (see FIG. 1) by the Reinforcement Learning algorithm 12. The website user simulator 20 yields the result of a travel product 52 being booked after having sorted the travel products offered on the website by their price. This might yield to a reward 220 of value “1” that is forwarded by the website user simulator 20 to the Reinforcement Learning algorithm 12. This might result in that the Learning activity 17 reinforces the action sort by price for this current state.

An example for an interrelation between environmental parameters and a Reinforcement Learning model is depicted by FIG. 5.

The system of the Reinforcement Learning module may comprise the following elements depicted in FIG. 5:
Cached queries: Queries may be cached in order to speed up learning—by being able to consider, e.g., the last 100 queries of certain user segments in the learning process
Flight server: The flight server maintains the search results with corresponding parameters (departure and arrival time, prices, connection flights etc.)
Environment settings 23: The environment settings 23 comprise the segment shares, hence the percentage of leisure passengers, business passengers etc. considered by the website user simulator 20, and data about the intent to book/intent to leave by segment.
The user simulator 20: The user simulator 20, for example, considers N passenger segments and decides with simulations on the kind of search performed by the passenger segments and on their behavior with regard to booking and/or leaving.

The elements of the system of FIG. 5 are in interaction with each other. As such, queries that are cached in the cached queries module are directed to the flight server. The cached queries as well as the results for these queries may be used to train the website user simulator 20. Furthermore, the environment settings may influence the user simulator 20 directly as they set the frame for the simulations performed.

Examples of the RL algorithm and the RL settings 13 are depicted in FIG. 5. The RL algorithm 12 may decide about the website change (such as flight ranking or website control arrangement) and may learn from user behavior. The RL settings 13, which influence the decisions and the learning performed by the RL algorithm 12 may comprise iterations for learning/testing and model parameters.

The production system, i.e., a system actually implementing the method according to the first aspect may be based on real users and searches, which are used to improve on initial learning of the Reinforcement Learning algorithm 12. The RL model 11 of the production system may be pre-trained based on simulation as explained above, and able to decide about changes implemented by an online travel agency, and may be able to be further trained on real user data.

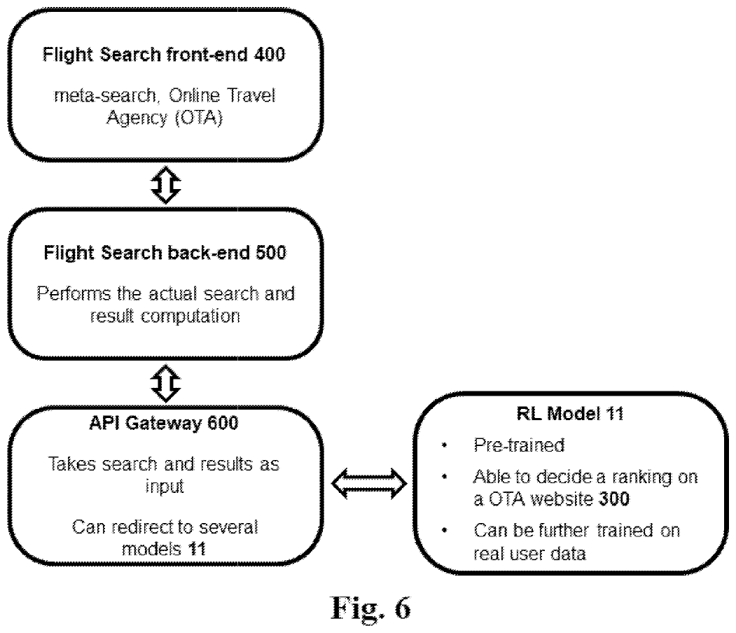

An example of a flight search environment in conjunction with a Reinforcement Learning model is visualized by FIG. 6.

A flight search front-end 400, for example, is provided by the online travel agency (OTA). This flight search front-end 400 may be in communication with a flight search back-end 500, which, for example, performs the actual search and result commutation, which may be based on a meta-search previously performed by the flight search front-end 400. The flight search back-end 500 may be in communication with the API gateway 600, which may take the search and the results yield in response to the search as an input and may redirect these to the RL model 11. The RL model 11 receives this data and is pre-trained, for example, by means of the simulated user queries received from the user simulator (the pretraining, for example, takes place in a learning phase). Furthermore, the RL model 11 may be able to decide a ranking of flight search results on an OTA website 300 or on an appearance of website controls 60. The RL model 11 can be further trained on real user data.

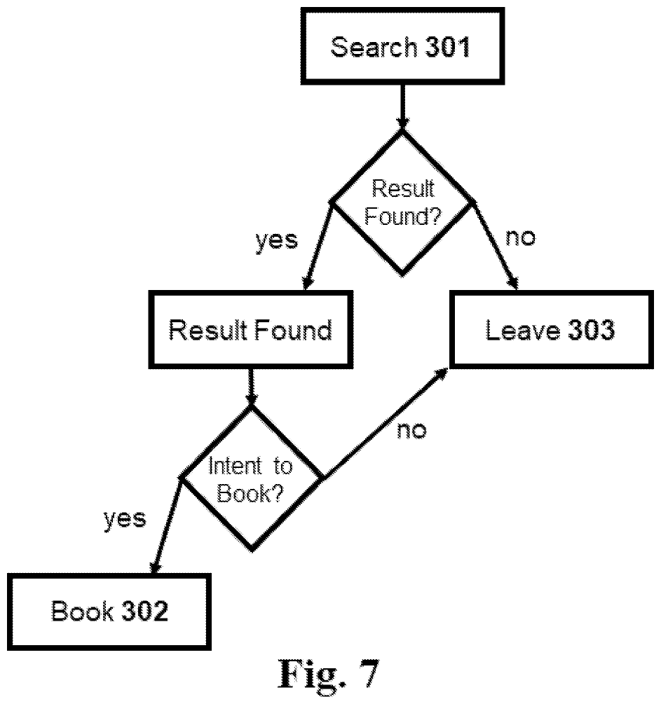

An example of a search tree considering whether or not search results that are suitable for the user are found and also considering which search results are found and whether or not there is an intent to book is illustrated by FIG. 7.

The intent to book specifies the extent of the simulated user to actually book a searched product, e.g., to users who search the search website for information purposes, but may decide to book the flight on a different website/different device at a later point and thus have no intent to book.

The intent to book is, for example, used for graphing KPI purposes and is used only in the learning phase, using the simulator. Hence, the intent to book may not be used in the subsequent production phase.

A search activity 301 is performed by the user simulator 20 (FIG. 4). It is then obtained, whether or not search results matching the needs of the user have been found. If no results are found, hence, there is no travel product 52 (FIG. 2) matching the needs of the user, the simulated user leaves 303 the search website without booking any travel product. If, however, search results are retrieved in the simulated search, it is checked whether the simulated user has an intent to book or not. It is simulated here, whether the user would actually have booked assuming he/she intended to book in the first place. The sequence arrives at “leave” 303 even if results have been found, in the case that the order or rank of elements in an ordered list of search results and/or the website controls did not satisfy the user in accordance with his/her (absent) intention to book.

As mentioned above, the intent to book feature models users who prefer to book later on another device, even if they found what they wanted. The effect on the simulation is that it makes the simulation more realistic since in reality, many passengers just search for information purposes, without intending to really book a certain travel product 52 (FIG. 2).

If the user has indeed an intent to book on the search website 300, the simulated search arrives at “book” 302. Otherwise, if the simulated user decides to book on a different platform or to book later, the simulated search ends at “leave” 303.

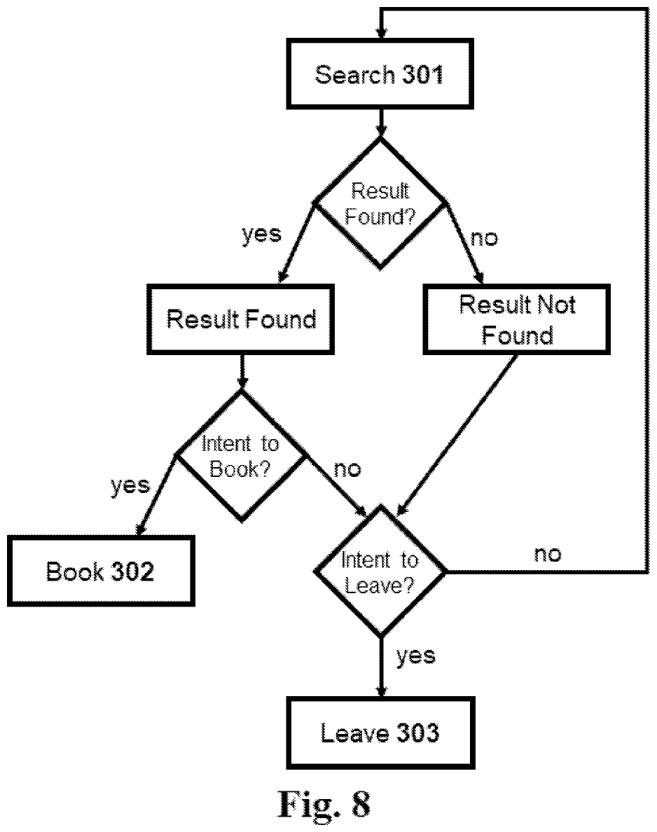

Another example of a search tree similar to the search tree of FIG. 7, but also considering an intent to leave is depicted by FIG. 8.

Different to what is shown by FIG. 7, in the scenario shown in FIG. 8, the simulated user not necessarily arrives at “leave” 303 when the user has no intent to book or the user has not found the desired result. When a desired result is not found by the simulated user or the simulated user has no intent to book, it is checked whether or not the simulated user has an intent to leave.

As also mentioned above, an intent to leave models whether or not a user makes another search after not booking on the current one. The effect on the simulation is also that the simulation becomes more realistic since many users do more than one search, immediately or hours/days later. These additional searches may be recognized with cookies. This may also help the algorithm to narrow down segments: a string of searches will make detecting the segments (leisure, business etc.) easier. This is the case, as through a lot of searches performed by the same user, it may be better identifiable to which segment the user belongs.

If the simulated user indeed has an intent to leave, the user arrives at “leave” 303. If, however, the user has no intent to leave, the user again arrives at the activity “search” 301, since the user might try a different search for a particular travel product 52 (FIG. 2).

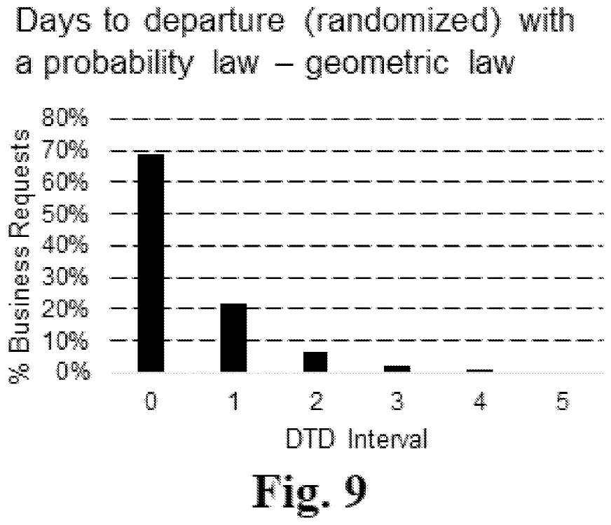

An example for a relation between the amount of days before departure of a travel product and the number of requests for such a travel product is illustrated by FIG. 9.

As explained above, the implementation of the website user simulator 20 and Reinforcement Learning algorithm 12, may consider multiple passenger segments, each with a different behavior in the state space.

As also mentioned above, these different search patterns and behavior may comprise: e.g., business passengers searching on work hours, leisure passengers having different days to departure (DTD) values. Furthermore, different passenger segments have interest in different flight characteristics (cheapest, fastest, combination . . . ).

The input for the search patterns of a certain user segment can be estimated from past bookings or stated preferences. As also mentioned above, the preferences do not have to be exactly accurate. It is sufficient to provide a pre-trained model with basic quality that can be refined and improved subsequently when being employed with the production system.

The example of FIG. 9 relates to a randomized day to departure (DTD) profile with a probability law for the passenger segment “business”.

In some examples, the passenger type is specified by one or more of: day of the week for searching, time of the day for searching, number of seats, number of days until departure, Saturday night stay, importance of travel product characteristics.

For the passenger segment “business”, a simulation variable “Day of week” may be set to a random number from 1 to 5. This means business searches usually relate to weekdays, and each weekday is equally probable. The probability for a Saturday night stay may be set to a 10% chance, the number of seats needed for transport may be set to one. The Day to Departure may be determined through a geometric law as the one depicted in FIG. 9. As such, in the example of FIG. 9, the probability for a booking on the same day as the intended departure is nearly 70%, whereas the probability for booking one day prior is slightly above 20% and the respective probabilities for a booking between two and five days prior to departure are below 10%.

All such criteria used in the website user simulator 20 may be varied during a simulation or may be predefined. The number of passenger segments and shares of the passenger segments may also be modified by parameter value adjustments, i.e., without changing the simulator itself.

The website searches performed are still random, but probability laws may depend on the passenger segment's parameters. In terms of the Reinforcement Learning parameters (agent, environment, state etc.), the passenger segment's parameters correspond to the state. The state may comprise any parameter defining the current environment. As such, a state may comprise user features and search features. The booking behavior by segment may be modelled by the intent to leave, the intent to book and a choice rule, e.g., deterministic cheapest, Multinomial logistic (MNL) choice model.

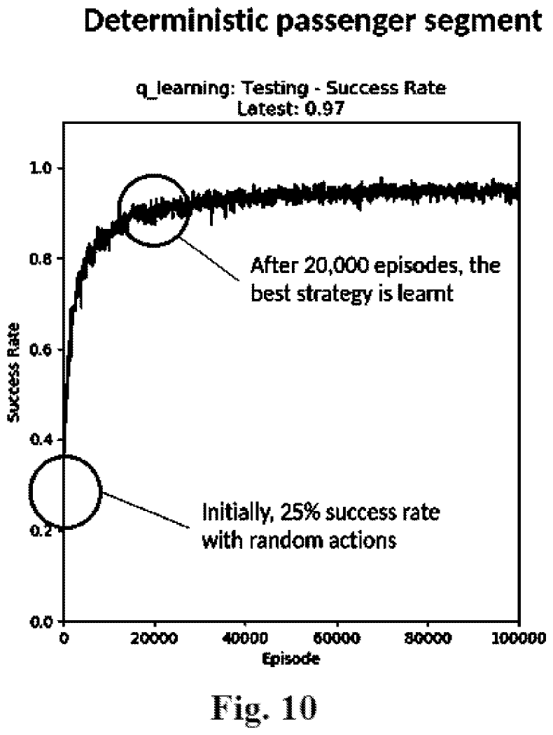

An example for a learning curve of the Reinforcement Learning model is illustrated by FIG. 10.

The learning curve given by FIG. 10 illustrates the relation between the number of learned episodes (x-Axis), an episode referring to the behavior of the user from the first search until the user either books or leaves, and the success rates of the simulation (y-Axis). It can be derived from this learning curve, that at an initial learning phase, with less than 1000 episodes learned, only a success rate of 25% can be achieved. However, after around 20000 episodes, a success rate of approximately 90% can be reached. The success rate continuously increases up to 97% (asymptotically) with a further increase of learning episodes.

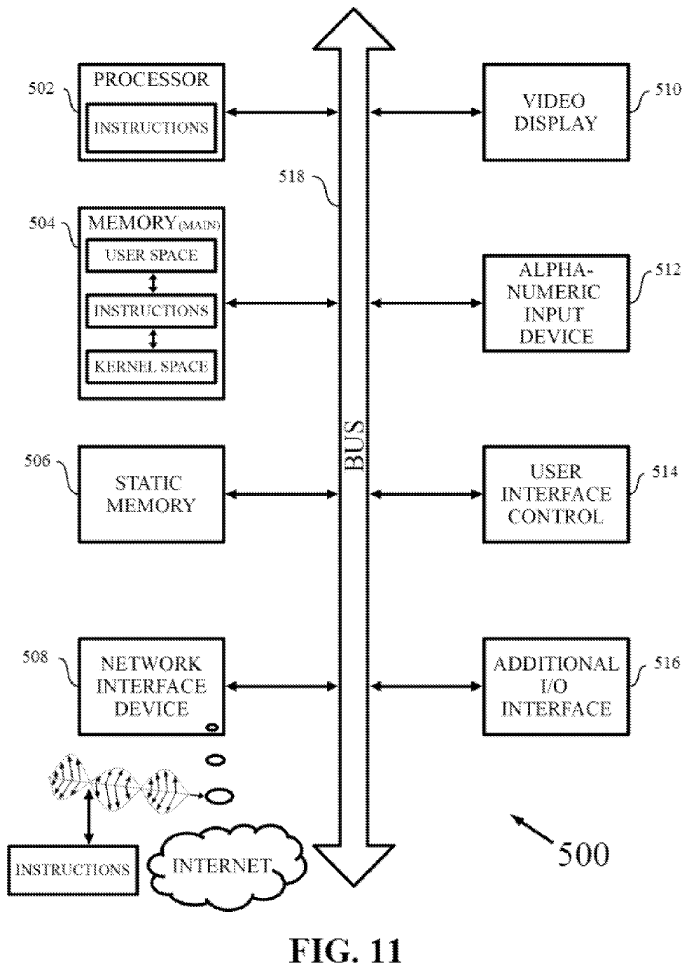

A diagrammatic representation of an exemplary computer system 500 is shown in FIG. 11. The computer system 500 is arranged to execute a set of instructions on processor 502, to cause the computer system 500 to perform a task as described herein.

The computer system 500 includes a processor 502, a main memory 504 and a network interface 508. The main memory 504 includes a user space, which is associated with user-run applications, and a kernel space, which is reserved for operating-system- and hardware-associated applications. The computer system 500 further includes a non-volatile or static memory 506, e.g., non-removable flash and/or solid-state drive and/or a removable Micro or Mini SD card, which permanently stores software enabling the computer system 500 to execute functions of the computer system 500. Furthermore, it may include a video display 510, a user interface control module 514 and/or an alpha-numeric and cursor input device 112. Optionally, additional I/O interfaces 516, such as card reader and USB interfaces may be present. The computer system components 502 to 509 are interconnected by a data bus 518.

In some examples the software programmed to carry out the method described herein is stored on the static memory 506; in other examples external databases are used.

An executable set of instructions (i.e., software) embodying any one, or all, of the methodologies described above, resides completely, or at least partially, permanently in the non-volatile memory 506. When being executed, process data resides in the main memory 504 and/or the processor 502. The executable set of instructions causes the processor to perform anyone of the methods described above.

Although certain products and methods constructed in accordance with the teachings of the invention have been described herein, the scope of coverage of this invention is not limited thereto. On the contrary, this patent covers all embodiments of the teachings of the invention fairly falling within the scope either literally or under the doctrine of equivalents.

What is claimed is:

1. A computer-implemented system for dynamically building and adapting a search website hosted by a webserver, the system comprising:
a learning module coupled to the webserver and employing a learning model for controlling appearance and/or functionality of the search website by generating actions to be output to the webserver, the actions relating to controlling an order and/or rank of elements in an ordered list of travel recommendations obtained as a result from a search request to be displayed by the search website and/or arranging website controls on the search website,
wherein the learning module is adapted to receive rewards, wherein the rewards are generated by the search website based on user input on the search website or by a website user simulator in response to one or more of the actions generated by the learning module based on state information provided by the web site user simulator, the rewards making the learning module to adapt the learning model, and
the website user simulator for simulating an input behavior of users of the search website and feeding the learning module to train the learning module.

2. The system of claim 1, wherein the search website is a travel website for booking travel products, and the actions comprise sorting travel products to be displayed on the travel website in response to a user search request according to one or more characteristics of the travel products and/or controlling an appearance of the website controls to be shown on the travel website.

3. The system of claim 2, wherein the one or more characteristics of the travel products include a price, a duration, a number of stops, a departure time, an arrival time, a type of travel provider, or a combination thereof.

4. The system of claim 3, wherein the website user simulator comprises simulation model with at least one of the following parameters describing the input behavior of users: a passenger segment, search behavior according to a passenger type, intention to book at a later point of time after a current search, or intention to conduct another search after the current search.

5. The system of claim 4, wherein the passenger segment includes business passenger, leisure passenger, senior passenger, or passenger visiting friend and relatives.

6. The system of claim 5, wherein the passenger type is specified by: day of the week for searching, time of the day for searching, number of seats, number of days until departure, Saturday night stay, or importance of travel product characteristics.

7. The system of claim 2, wherein the website user simulator comprises a simulation model with at least one of the following parameters describing the user input behavior: a passenger segment, search behavior according to a passenger type, intention to book at a later point of time after a current search, or intention to conduct another search after the current search.

8. The system of claim 2, wherein the rewards relate to whether or not the user books one of the travel products displayed on the travel website.

9. The system of claim 1, further comprising:
the webserver hosting the search website.

10. A computer-implemented method for dynamically building and adapting a search website hosted by a webserver, the method comprising:
coupling a learning module to the webserver;
employing a learning model for controlling appearance and/or functionality of the search website by generating actions to be output to the webserver, wherein the actions relate to controlling an order and/or rank of elements in an ordered list of travel recommendations obtained as a result from a search request to be displayed by the search website and/or arranging website controls on the search website; and
receiving rewards at the learning module, wherein the rewards are generated by the search website based on user input on the search website or by a website user simulator in response to one or more of the actions generated by the learning module based on state information provided by the website user simulator, the rewards making the learning module to adapt the learning model, and the website user simulator for simulating an input behavior of users of the search website and feeding the learning module to train the learning module.

11. The method of claim 10, wherein the search website is a travel website for booking travel products, and the actions comprise sorting travel products to be displayed on the travel website in response to a user search request according to one or more characteristics of the travel products and/or controlling an appearance of the website controls to be shown on the travel website.

12. The method of claim 11, wherein the one or more characteristics of the travel products include a price, a duration, a number of stops, a departure time, an arrival time, a type of travel provider, or a combination thereof.

13. The method of claim 12, wherein the website user simulator comprises simulation model with at least one of the following parameters describing the input behavior of users: a passenger segment, search behavior according to a passenger type, intention to book at a later point of time after a current search, or intention to conduct another search after the current search.

14. The method of claim 13, wherein the passenger segment includes business passenger, leisure passenger, senior passenger, or passenger visiting friend and relatives.

15. The method of claim 14, wherein the passenger type is specified by: day of the week for searching, time of the day for searching, number of seats, number of days until departure, Saturday night stay, or importance of travel product characteristics.

16. The method of claim 11, wherein the website user simulator comprises a simulation model with at least one of the following parameters describing the user input behavior: a passenger segment, search behavior according to a passenger type, intention to book at a later point of time after a current search, or intention to conduct another search after the current search.

17. The method of claim 11, wherein the rewards relate to whether or not the user books one of the travel products displayed on the travel website.

18. The method of claim 10, wherein the webserver hosts the search website.
